(19) United States
(12) Patent Application Publication
(10) Pub. No.: US 2011/0161023 A1
(43) Pub. Date: Jun. 30, 2011

(54) SYSTEM AND METHOD FOR MEASURING MACHINE ENERGY CONSUMPTION AND PRODUCTIVITY

(75) Inventors: CHI-CHIH WANG, Tu-Cheng (TW); RUI-JUN WANG, Shenzhen City (CN); XU-KUN WANG, Shenzhen City (CN); ZHI-LONG LI, Shenzhen City (CN)

(73) Assignees: GDS SOFTWARE (SHENZHEN) CO.,LTD, ShenZhen City (CN); HON HAI PRECISION INDUSTRY CO., LTD., Tu-Cheng (TW)

(21) Appl. No.: 12/848,210

(22) Filed: Aug. 1, 2010

(30) Foreign Application Priority Data
Dec. 29, 2009 (CN) 200910312537.0

(51) Int. Cl. G06F 19/00; G01R 21/06

(52) U.S. Cl. 702/62; 702/188

(57) ABSTRACT

A server in electronic communication with at least one data acquisition unit via a wireless receiver. The server measures energy consumption and productivity of a machine. The machine is installed with a current analyzer and a detection unit, and wirelessly connects to the at least one data acquisition unit. The current analyzer measures the energy consumption of the machine. The detection unit calculates the productivity of the machine. After a search command is sent to the wireless receiver, a usable data acquisition unit collects the energy consumption and the productivity of the machine. The server analyzes the energy consumption and productivity of the machine and generates an analysis chart. The analysis chart is displayed on a display screen.

### TECHNICAL FIELD

Embodiments of the present disclosure generally relate to measuring systems and methods, and more particularly to a system and method for measuring energy consumption and productivity of a machine, such as a production line machine.

### DESCRIPTION OF RELATED ART

Currently, energy consumption and productivity of a machine on a production line are determined by accessing data of the machine using a computer that is hardwired to the machine. In other words, the data needed to determine efficiency of the machine cannot be retrieved wirelessly by a remote computer.

### BRIEF DESCRIPTION OF THE DRAWINGS

FIG. 1 is a schematic diagram of one embodiment of a system for measuring energy consumption and productivity of a machine.

FIG. 2 is a circuit diagram of one embodiment of a current analyzer of FIG. 1.

FIG. 3 is a circuit diagram of one embodiment of a detection unit of FIG. 1.

FIG. 4 is a block diagram of one embodiment of function modules of the system for measuring energy consumption and productivity of the machine of FIG. 1.

FIG. 5 is a flowchart illustrating one embodiment of a method for measuring energy consumption and productivity of a machine.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

In general, the data “module,” as used herein, refers to logic embodied in hardware or firmware, or to a collection of software instructions, written in a programming language, such as, for example, Java, C, or assembly. One or more software instructions in the modules may be embedded in firmware, such as an EPROM. It will be appreciated that modules may comprised connected logic units, such as gates and flip-flops, and may comprise programmable units, such as programmable gate arrays or processors. The modules described herein may be implemented as either software and/or hardware modules and may be stored in any type of computer-readable medium or other computer storage device.

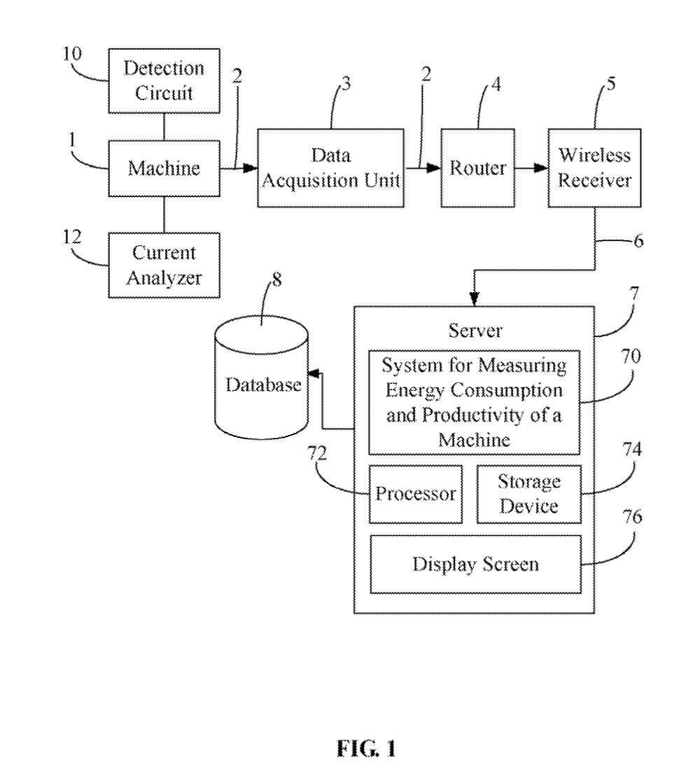

FIG. 1 is a schematic diagram of one embodiment of a server 7 comprising a system 70. The system 70 can be used to measure energy consumption and productivity of a machine 1. The machine 1 comprises a detection unit 10, and a current analyzer 12. In the embodiment, three-phase power is used to provide power to the machine 1, and the three-phase power may have three live wires. The current analyzer 12 may be a current transformer, and is connected to any one of the three live wires. In one embodiment, the machine 1 connects to at least one data acquisition unit 3 (only one data acquisition unit 3 is shown in FIG. 1) via a wireless network 2. The at least one data acquisition unit 3 wirelessly connects to a wireless receiver 5. The server 7 connects to the wireless receiver 5 via a network 6, and connects to a database 8. The database 8 is used to store the energy consumption and the productivity of the machine 1.

In one embodiment, the wireless network 2 can comply with the ZigBee protocol, and each data acquisition unit 3 has a wireless transmission function. The network 6 can be an ethernet, an Intranet, or an Internet, for example. The server 7 can be a supervisory control and data acquisition (SCADA) server, an access point device, or a personal computer, for example. In the embodiment, a SCADA server is given as an example of the server 7.

To ensure reliable wireless communication between the wireless receiver 5 and the data acquisition unit 3 over a desired distance, a router 4 is employed.

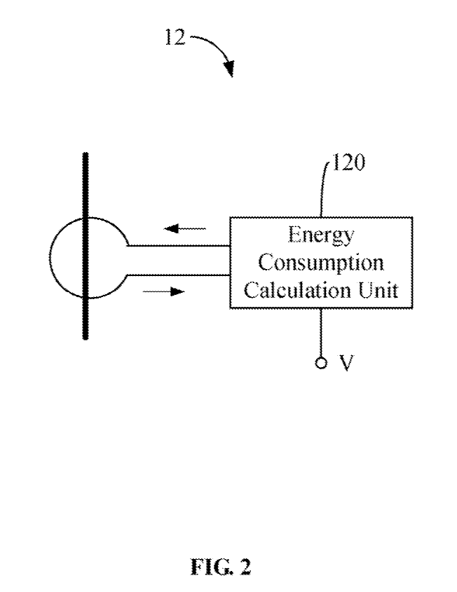

In the embodiment, the current analyzer 12 (as shown in FIG. 2) uses an energy consumption calculation unit 120 to measure current flow in the live wire and calculate energy consumption during predetermined intervals of the machine 1 (for example, every two seconds). The energy consumption of the machine 1 during each interval equals “\sqrt{3}VI,” where “V” is voltage supplied to the machine 1, and “I” is current drawn by the machine 1. The energy consumption calculation unit 120 accumulates the energy consumption measurements of the machine 1 of each interval to obtain a total energy consumption of the machine 1.

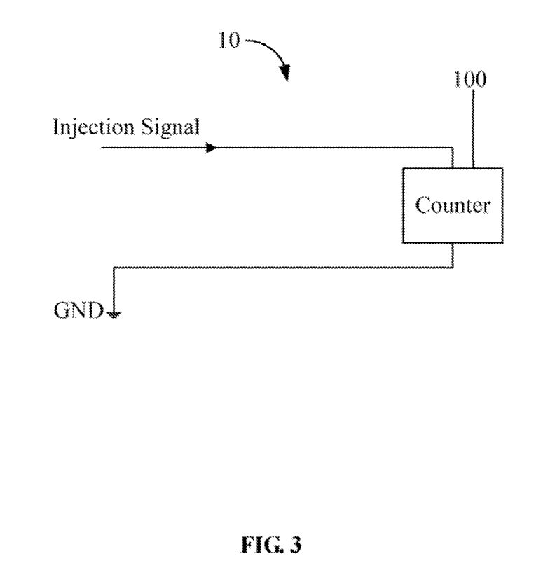

The detection unit 10 uses a counter 100 (as shown in FIG. 3) to count the number of items produced or manufactured by the machine 1, to calculate the productivity of the machine 1. For example, the counter 100 counts number of injections of an injection molding machine to obtain the productivity of the machine 1.

The data acquisition unit 3 collects the energy consumption of the machine 1 measured by the current analyzer 12, and collects the productivity of the machine 1 calculated by the detection unit 10. In order to obtain an accurate energy consumption of the machine 1, the data acquisition unit 3 stores a correction parameter for correcting the energy consumption of the machine 1 if needed.

The wireless receiver 5 receives the energy consumption and the productivity of the machine 1 collected by the data acquisition unit 3 via the router 4.

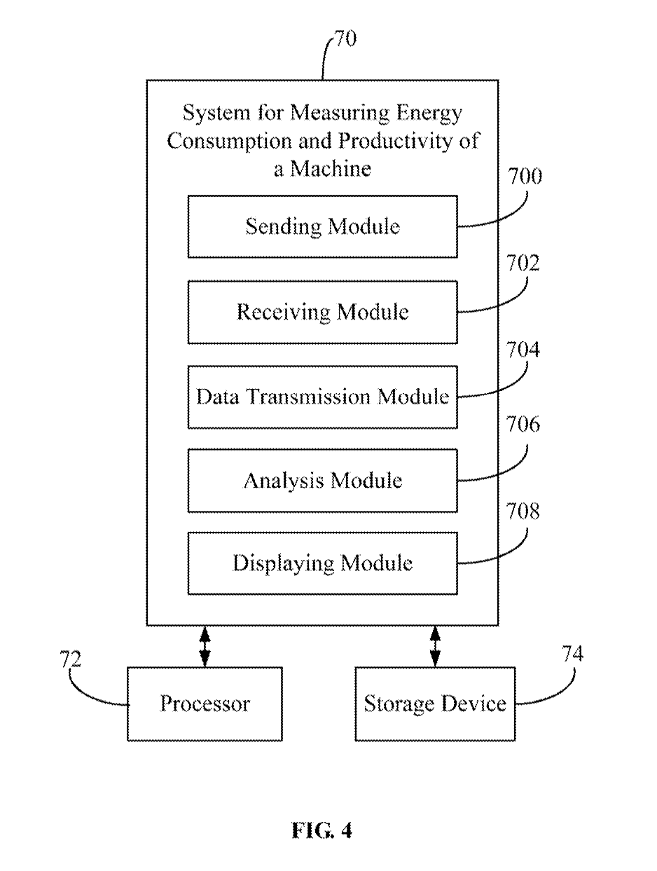

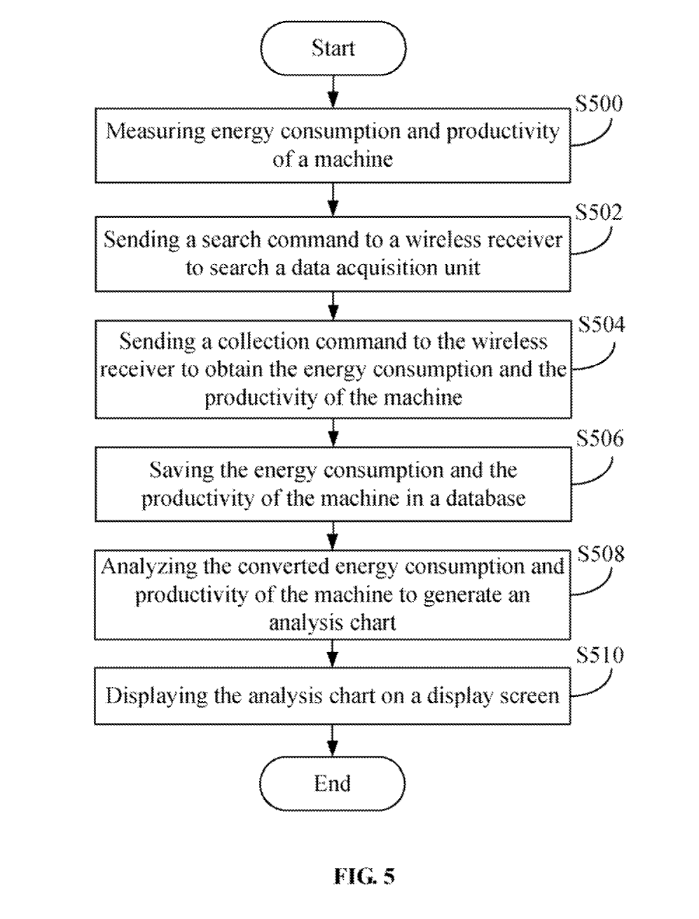

In the embodiment, the server 7 includes the system 70, at least one processor 72, a storage device 74, and a display screen 76. As illustrated in FIG. 4, the system 70 includes a sending module 700, a receiving module 702, a data transmission module 704, an analysis module 706, and a displaying module 708. Each of the modules 700-708 may include one or more computerized instructions or codes, which is stored in the storage device 74, and can be executed by the at least one processor 72. The storage device 74 may be a hard disk drive, a compact disc, a digital video disc, or a tape drive. Detail functions of the modules 700-708 can be described as below in FIG. 5.

FIG. 5 is a flowchart illustrating one embodiment of a method for measuring energy consumption and productivity of a machine 1.

In block S500, the current analyzer 12 (as shown in FIG. 2) uses the energy consumption calculation unit 120 to measure energy consumption during predetermined intervals of the machine 1 (for example, every two seconds), and accumulate the energy consumption measurements of the machine 1 during each interval to obtain a total energy consumption of the machine 1. The detection unit 10 further uses a counter 100 (as shown in FIG. 3) to count the number of items produced or manufactured by the machine 1, and to calculate the productivity of the machine 1. The energy consumption and the productivity of the machine 1 can be collected by the data acquisition unit 3.

In block S502, the sending module 700 sends a search command to the wireless receiver 5 to search an usable data acquisition unit 3. In the embodiment, one workshop may contain many machines 1, and a plurality of data acquisition units 3 may be near the machines 1. The sending module 700 searches a usable data acquisition unit 3 from the at least one data acquisition unit 3.

In block S504, the sending module 700 sends a collection command to the wireless receiver 5 to obtain the energy consumption and the productivity of the machine 1 collected by the usable data acquisition unit 3.

In block S506, the receiving module 702 receives the energy consumption and the productivity of the machine 1 transmitted from the wireless receiver 5, converts data format of the energy consumption and the productivity of the machine 1, the data transmission module 704 transmits the converted energy consumption and the converted productivity of the machine 1 to the database 8. For example, the energy consumption and the productivity of the machine 1 may be coded in hexadecimal, the receiving module 702 converts the hexadecimal units into binary units.

In block S508, the analysis module 706 analyzes the converted energy consumption and the converted productivity of the machine 1, and generates an analysis chart according to the analysis results. In one embodiment, the analysis chart contains the energy consumption and the productivity of the machine 1 in each production or manufacture. In other embodiments, the analysis chart may contain the energy consumptions and the productivities of all the same types of machines 1.

In block S510, the displaying module 708 displays the analysis chart on the display screen 76.

Although certain inventive embodiments of the present disclosure have been specifically described, the present disclosure is not to be construed as being limited thereto. Various changes or modifications may be made to the present disclosure without departing from the scope and spirit of the present disclosure.

What is claimed is:

1. A server in electronic communication with at least one data acquisition unit via a wireless receiver, the server comprising:
a sending module operable to send a search command to the wireless receiver to search a data acquisition unit near a machine, and send a data collection command to the wireless receiver to obtain energy consumption and productivity of the machine collected by the data acquisition unit;
a receiving module operable to receive the energy consumption and the productivity of the machine, and convert data format of the energy consumption and the productivity of the machine;
a data transmission module operable to transmit the converted energy consumption and productivity of the machine to a database;
an analysis module operable to analyze the converted energy consumption and productivity of the machine to generate an analysis chart; and
a displaying module operable to display the analysis chart on a display screen of the server.

2. The system as claimed in claim 1, wherein the at least one data acquisition unit is wirelessly connected to the machine installed with a current analyzer and a detection unit.

3. The system as claimed in claim 2, wherein the current analyzer uses an energy consumption calculation unit to measure energy consumption during predetermined intervals of the machine, and accumulate the energy consumption measurements of the machine of each interval to obtain a total energy consumption of the machine.

4. The system as claimed in claim 1, wherein the detection unit uses a counter to count the number of items produced or manufactured by the machine, to obtain the productivity of the machine.

5. The system as claimed in claim 1, wherein the wireless receiver is connected to the data acquisition unit via a router.

6. The system as claimed in claim 1, wherein the data acquisition unit stores a correction parameter for correcting the energy consumption of the machine.

7. A method for measuring energy consumption and productivity of a machine, the method comprising:
measuring energy consumption of the machine by using a current analyzer, and calculating productivity of the machine by using a detection unit;
sending a search command to a wireless receiver to search a data acquisition unit near the machine;
obtaining the energy consumption and the productivity of the machine collected by the data acquisition unit;
converting data format of the energy consumption and the productivity of the machine;
transmitting the converted energy consumption and productivity to a database;
analyzing the converted energy consumption and productivity of the machine to generate an analysis chart; and
displaying the analysis chart on a display screen.

8. The method as claimed in claim 7, wherein the data acquisition unit is wirelessly connected to the machine, and the current analyzer and the detection unit are installed in the machine.

9. The method as claimed in claim 7, wherein the wireless receiver is connected to the data acquisition unit via a router.

10. The method as claimed in claim 7, wherein the energy consumption of the machine is obtained by measuring energy consumption during predetermined intervals of the machine, and by accumulating the energy consumption measurements of the machine of each interval.

11. The method as claimed in claim 7, wherein the productivity of the machine is obtained by counting the number of items produced or manufactured by the machine using a counter.

12. A storage medium having stored thereon instructions that, when executed by at least one processor of a server, causes the server to perform a method for measuring an energy consumption and a productivity of a machine, the method comprising:
measuring energy consumption of the machine by using a current analyzer, and calculating productivity of the machine by using a detection unit;
sending a search command to a wireless receiver to search a data acquisition unit near the machine;
obtaining the energy consumption and the productivity of the machine collected by the data acquisition unit;
converting data format of the energy consumption and the productivity of the machine;
transmitting the converted energy consumption and productivity to a database;
analyzing the converted energy consumption and productivity of the machine to generate an analysis chart; and
displaying the analysis chart on a display screen.

13. The storage medium according to claim 12, wherein the data acquisition unit is wirelessly connected to the machine, and the current analyzer and the detection unit are installed in the machine.

14. The storage medium according to claim 12, wherein the wireless receiver is connected to the data acquisition unit via a router.

15. The storage medium according to claim 12, wherein the energy consumption of the machine is obtained by measuring energy consumption during predetermined intervals of the machine, and by accumulating the energy consumption measurements of the machine of each interval.

16. The storage medium according to claim 12, wherein the productivity of the machine is obtained by counting the number of items produced or manufactured by the machine using a counter.
